(19) United States
(12) Patent Application Publication
(10) Pub. No.: US 2021/0404054 A1
(43) Pub. Date: Dec. 30, 2021

(54) Highly-ordered nano-structure array and Fabricating Method thereof

(71) Applicant: National Taiwan University of Science and Technology, Taipei City (TW)

(72) Inventors: Jinn P. CHU, Taipei City (TW); Kuan Wei TSENG, Taipei City (TW)

(21) Appl. No.: 16/940,416

(22) Filed: Jul. 28, 2020

(30) Foreign Application Priority Data
Jun. 29, 2020 (TW) 109121906

(51) Int. Cl. C23C 14/58; B82B 1/00; B82B 3/00; C23C 14/18

(52) U.S. Cl. CPC C23C 14/5873; C23C 14/18; B82B 3/0014; B82B 1/008

(57) ABSTRACT

A highly-ordered nano-structure array, formed on a substrate, mainly comprises a plurality of highly-ordered nano-structure units. Each of the highly-ordered nano-structure units forms a receiving compartment. One end of the receiving compartment opposite to the substrate has an opening. Each of the highly-ordered nano-structure units comprises at least one thin film layer. A periphery and a bottom of the receiving compartment are defined by an inner surface of a surrounding portion of the at least one thin film layer and a top surface of a bottom portion of the at least one thin film layer, respectively. The at least one thin film layer is made of at least one material selected from the group consisting of: metal, alloy, oxide, nitride, and sulfide.

### FIELD OF THE INVENTION

The present invention is related to a nano-structure array with highly ordered periodicity, especially a nano-structure array having a plurality of nano-structure units formed by a thin film layer or multiple thin film layers, wherein any adjacent thin film layers are made of different materials.

### BACKGROUND OF THE INVENTION

Nanotechnology is becoming more and more widely used in a variety of applications, such as biomedicine and biological detecting and analyzing technology. Different materials have different characteristics and applications. Due to the different combinations of materials, the surface charging characteristics, selectivity, catalytic activity and other characteristics will also change when coating the outer shell on the structure of the inner core. Through the selection and design of different materials, the electrical, catalytic, optical, and magnetic properties can be applied to different functions. The nanotubes array made of zirconium-based metallic glass of conventional technology is used as a sensing device to sense the characteristics and optical characteristics of a specific target attached to the surface of the nanotubes. The nanotubes array made of zirconium-based metallic glass is not suitable to be used in the fields of catalysis or surface-enhanced Raman scattering. Hence, other different materials must be used for fabricating nanotubes array to meet the needs of different applications. Or the nanotubes array made of zirconium-based metallic glass or other metal based metallic glass may be coated with other different materials, thereby changing the surface charging characteristics, selectivity, catalytic activity, and other characteristics of the metallic glass for application in different fields.

### SUMMARY OF THE INVENTION

The main technical problem that the present invention aims to solve is to provide different materials or different combination of materials to fabricate nanotubes array to meet the needs of different applications. Accordingly, the present invention has developed a new design which may avoid the above-described drawbacks, may significantly enhance the performance of the devices and may take into account economic considerations. Therefore, the present invention then has been invented.

In order to solve the above described problems and to achieve the expected effect, the present invention provides a highly-ordered nano-structure array formed on a substrate. The highly-ordered nano-structure array comprises a plurality of highly-ordered nano-structure units. Each of the highly-ordered nano-structure units forms a receiving compartment. One end of the receiving compartment opposite to the substrate has an opening. Each of the highly-ordered nano-structure units comprises a first thin film layer. A periphery and a bottom of the receiving compartment are defined by an inner surface of a surrounding portion of the first thin film layer and a top surface of a bottom portion of the first thin film layer, respectively. Therefore, the plurality of highly-ordered nano-structure units composed of a single thin film layer (the first thin film layer) are formed, wherein the highly-ordered nano-structure units are made of at least one material selected from the group consisting of: metal, alloy, oxide, nitride and sulfide. By selecting appropriate material(s) of the first thin film layer, the highly-ordered nano-structure array can be applied to the desired field.

Moreover, the present invention further provides a highly-ordered nano-structure array formed on a substrate. The highly-ordered nano-structure array comprises a plurality of highly-ordered nano-structure units. Each of the highly-ordered nano-structure units forms a receiving compartment. One end of the receiving compartment opposite to the substrate has an opening. Each of the highly-ordered nano-structure units comprises a plurality of thin film layers. The plurality of thin film layers comprises a first thin film layer and a second thin film layer. A periphery and a bottom of the receiving compartment are defined by an inner surface of a surrounding portion of the first thin film layer and a top surface of a bottom portion of the first thin film layer, respectively. A bottom portion of the second thin film layer is located between the substrate and the bottom portion of the first thin film layer. The surrounding portion of the first thin film layer is located between a surrounding portion of the second thin film layer and the receiving compartment. Therefore, the highly-ordered nano-structure units composed of the plurality of thin film layers (including the first thin film layer and the second thin film layer) are formed, wherein the plurality of thin film layers are made of at least one material selected from the group consisting of: metal, alloy, oxide, nitride and sulfide, wherein any two adjacent thin film layers of the plurality of thin film layers are made of different materials. By selecting appropriate combination of materials of the first thin film layer and the second thin film layer, the highly-ordered nano-structure array can be applied to the desired field.

In implementation of the highly-ordered nano-structure array, the plurality of thin film layers further comprises a third thin film layer. The third thin film layer is formed between the first thin film layer and the second thin film layer. Therefore, the highly-ordered nano-structure units composed of the plurality of thin film layers (including the first thin film layer, the second thin film layer, and the third thin film layer) are formed, wherein the first thin film layer and the second thin film layer are made of at least one material selected from the group consisting of: metal, alloy, oxide, nitride and sulfide, wherein the third thin film layer is made of at least one material selected from the group consisting of: metal, alloy, oxide, nitride, sulfide, carbide and diamond, wherein any two adjacent thin film layers of the plurality of thin film layers are made of different materials. By selecting appropriate combination of materials of the first thin film layer, the second thin film layer and the third thin film layer, the highly-ordered nano-structure array can be applied to the desired field.

In implementation of the highly-ordered nano-structure array, the first thin film layer and the second thin film layer are made of the same material. Hence, the third thin film layer is an inner core layer, while the first thin film layer and the second thin film layer are the outer shell layers. The characteristics of the first thin film layer (the second thin film layer) and the third thin film layer affect each other. By selecting appropriate combination of materials of the first thin film layer (the second thin film layer) and the third thin film layer, the highly-ordered nano-structure array can be applied to the desired field.

In implementation of the highly-ordered nano-structure array, the plurality of thin film layers further comprises at least one fourth thin film layer, wherein the at least one fourth thin film layer is formed (a) between the third thin film layer and the first thin film layer, (b) between the second thin film layer and the third thin film layer, or (c) between the third thin film layer and the first thin film layer and between the second thin film layer and the third thin film layer. Therefore, the highly-ordered nano-structure units composed of the plurality of thin film layers (including the first thin film layer, the second thin film layer, the third thin film layer, and the at least one fourth thin film laver) are formed, wherein the first thin film layer and the second thin film layer are made of at least one material selected from the group consisting of: metal, alloy, oxide, nitride and sulfide, wherein the third thin film layer and the at least one fourth thin film layer are made of at least one material selected from the group consisting of: metal, alloy, oxide, nitride, sulfide, carbide and diamond, wherein any two adjacent thin film layers of the plurality of thin film layers are made of different materials. By selecting appropriate combination of materials of the first thin film layer, the second thin film layer, the third thin film layer, and the at least one fourth thin film layer, the highly-ordered nano-structure array can be applied to the desired field.

In implementation of the highly-ordered nano-structure array, the third thin film layer is made of at least one material selected from the group consisting of: bronze, brass, nickel alloy, stainless steel, silicon carbide, tungsten carbide, diamond, tungsten, tungsten alloy, and WNiB metallic glass. The first thin film layer is made of at least one material selected from the group consisting of: bronze, brass, nickel alloy, and stainless steel. The second thin film layer is made of at least one material selected from the group consisting of: bronze, brass, nickel alloy, and stainless steel. The at least one fourth thin film layer is made of at least one material selected from the group consisting of: bronze, brass, nickel alloy, stainless steel, silicon carbide, tungsten carbide, diamond, tungsten, tungsten alloy, and WNiB metallic glass.

In implementation of the highly-ordered nano-structure array, the third thin film layer has a thickness greater than or equal to 5 nm, and less than or equal to 1 μm. The second thin film layer has a thickness greater than or equal to 5 nm, and less than or equal to 1 μm. The first thin film layer has a thickness greater than or equal to 5 nm, and less than or equal to 1 μm.

In implementation of the highly-ordered nano-structure array, wherein each of the highly-ordered nano-structure units is a nanotube, wherein the nanotube is a cylindrical nanotube or an elliptical cylindrical nanotube.

In implementation of the highly-ordered nano-structure array, wherein each of the highly-ordered nano-structure units has a thickness greater than or equal to 10 nm, and less than or equal to 20 μm. The nanotube has a diameter greater than or equal to 100 nm, and less than or equal to 100 μm. The nanotube has a thickness and a diameter, the ratio of the thickness of the nanotube to the diameter of the nanotube is greater than or equal to 0.001, and less than or equal to 0.5. The nanotube has a height and a diameter, the ratio of the height of the nanotube to the diameter of the nanotube is greater than or equal to 0.05, and less than or equal to 5.

Moreover, the present invention further provides a fabricating method of highly-ordered nano-structure array comprising following steps of: Step A: forming a sacrificial layer on a substrate, wherein the sacrificial layer is made of at least one material selected from the group consisting of: semiconductor epitaxial structure, metal, alloy, oxide, and nitride; Step B: patterning the sacrificial layer to provide a plurality of recesses; Step C: forming at least one thin film layer on a top surface of the sacrificial layer and an inner surface of each of the plurality of recesses; Step D: etching the at least one thin film layer formed on the top surface of the sacrificial layer such that the sacrificial layer is exposed; and Step E: removing the sacrificial layer.

For further understanding the characteristics and effects of the present invention, some preferred embodiments referred to drawings are in detail described as follows.

### BRIEF DESCRIPTION OF DRAWINGS

FIG. 1 is the cross-sectional schematic view showing an embodiment of a highly-ordered nano-structure array of the present invention.

FIG. 2 is the cross-sectional schematic view showing another embodiment of a highly-ordered nano-structure array of the present invention.

FIG. 3 is the cross-sectional schematic view showing an embodiment of a highly-ordered nano-structure array of the present invention.

FIG. 4 is the cross-sectional schematic view showing another embodiment of a highly-ordered nano-structure array of the present invention.

FIG. 5 is the perspective schematic view showing the fabricating processes of a highly-ordered nano-structure array of the present invention.

FIG. 6 shows the images of the scanning electron microscope of embodiments of a highly-ordered nano-structure array of the present invention.

FIG. 7 shows the images of the scanning electron microscope of another embodiment of a highly-ordered nano-structure array of the present invention.

FIG. 8 shows the images of the scanning electron microscope of an embodiment of a highly-ordered nano-structure array of the present invention when applied as a carrier.

### DETAILED DESCRIPTIONS OF PREFERRED EMBODIMENTS

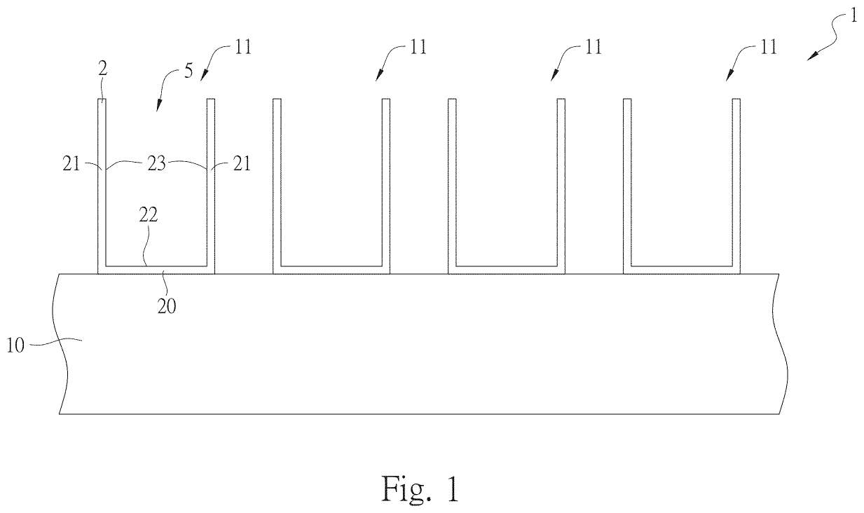

Please refer to FIG. 1, which is the cross-sectional schematic showing an embodiment of a highly-ordered nano-structure array of the present invention. A highly-ordered nano-structure array 1 of the present invention is formed on a substrate 10. The highly-ordered nano-structure array 1 comprises a plurality of highly-ordered nano-structure units 11. Each of the highly-ordered nano-structure units 11 forms a receiving compartment 5. One end of the receiving compartment 5 opposite to the substrate 10 has an opening. Each of the highly-ordered nano-structure units 11 comprises a first thin film layer 2. A periphery and a bottom of the receiving compartment 5 are defined by an inner surface 23 of a surrounding portion 21 of the first thin film layer 2 and a top surface 22 of a bottom portion 20 of the first thin film layer 2, respectively. In current embodiment, each of the highly-ordered nano-structure units 11 is a nanotube (cylindrical nanotube). The first thin film layer 2 is made of at least one material selected from the group consisting of: metal, alloy, oxide, nitride and sulfide. In some embodiments, the metal is at least one selected from the group consisting of: Be, Mg, Al, Ti, V, Cr, Mn, Fe, Co, Ni, Cu, Zn, Ga, Ge, Y, Zr, Nb, Mo, Ru, Rh, Pd, Ag, Cd, In, Sn, Sb, Hf, Ta, W, Pt, Au, and Pb. In some embodiments, the alloy is at least one selected from the group consisting of: Be alloy, Mg alloy, Al alloy, Ti alloy, V alloy, Cr alloy, Mn alloy, Fe alloy, Co alloy, Ni alloy, Cu alloy, Zn alloy, Ga alloy, Ge alloy, Y alloy, Zr alloy, Nb alloy, Mo alloy, Ru alloy, Rh alloy, Pd alloy, Ag alloy, Cd alloy, In alloy, Sn alloy, Sb alloy, Hf alloy, Ta alloy, W alloy, Pt alloy, Au alloy, and Pb alloy. In some embodiments, the oxide is at least one selected from the group consisting of: aluminum oxide, titanium dioxide, silicon oxide, and zinc oxide. In some embodiments, the nitride is at least one selected from the group consisting of: silicon nitride, gallium nitride, arsenic nitride, and titanium nitride. In some embodiments, the sulfide is at least one selected from the group consisting of: cadmium sulfide, lead sulfide, and molybdenum sulfide. In some preferred embodiments, the first thin film layer 2 is made of at least one material selected from the group consisting of: bronze, brass, nickel alloy (such as Inconel 718 nickel alloy), stainless steel (such as 316 stainless steel), gold, silver, and zinc oxide. By selecting different materials, the nanotubes can be applied to different fields. For example, by selecting the nanotubes made of metals or alloys, the nanotubes are suitable for applications in catalysis, surface-enhanced Raman scattering, biomedical applications, etc. For example, the nanotubes made of aluminum oxide or zinc oxide, the nanotubes can be applied for optical properties or can be used as a drug carrier, etc. The nanotube has a thickness (that is a thickness of the highly-ordered nano-structure unit 11, or a thickness of the first thin film layer 2), a height, and a diameter. In some embodiments, the thickness of the nanotube is greater than or equal to 10 nm, and less than or equal to 20 μm. In some preferred embodiments, the thickness of the nanotube is greater than or equal to 50 nm, and less than or equal to 500 nm. In some embodiments, the diameter of the nanotube is greater than or equal to 100 nm, and less than or equal to 100 μm. In some preferred embodiments, the diameter of the nanotube is greater than or equal to 300 nm, and less than or equal to 20 μm. In some embodiments, the ratio of the thickness of the nanotube to the diameter of the nanotube is greater than or equal to 0.001, and less than or equal to 0.5. In some preferred embodiments, the ratio of the thickness of the nanotube to the diameter of the nanotube is greater than or equal to 0.01, and less than or equal to 0.2. In some embodiments, the ratio of the height of the nanotube to the diameter of the nanotube is greater than or equal to 0.05, and less than or equal to 5. In some preferred embodiments, the ratio of the height of the nanotube to the diameter of the nanotube is greater than or equal to 0.1, and less than or equal to 2. In the highly-ordered nano-structure array 1 formed by the plurality of highly-ordered nano-structure units 11, the duty ratio of the plurality of highly-ordered nano-structure units 11 is greater than or equal to 0.5, and less than or equal to 6. In some preferred embodiments, the duty ratio is greater than or equal to 0.5, and less than or equal to 2. In some other embodiments, each of the highly-ordered nano-structure units 11 may be other shapes, for example, elliptical cylindrical nanotubes. In some embodiments, a cross section of each of the highly-ordered nano-structure units 11 may be a triangle, a square, a rectangle, a trapezoid, a circle, an ellipse, or a polygon.

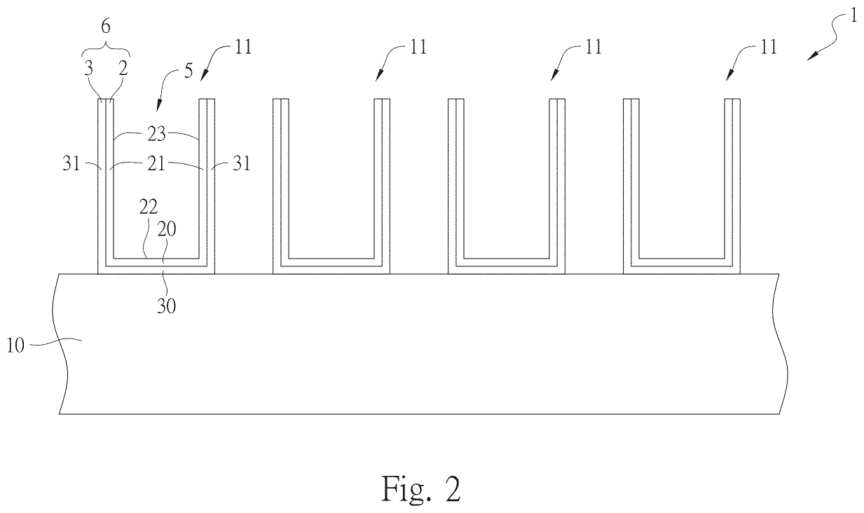

Please refer to FIG. 2, which is the cross-sectional schematic showing another embodiment of a highly-ordered nano-structure array of the present invention. The main structure of the embodiment of FIG. 2 is basically the same as the structure of the embodiment of FIG. 1, except that each of the highly-ordered nano-structure units 11 comprises a plurality of thin film layers 6, wherein the plurality of thin film layers 6 comprises a second thin film layer 3 and the first thin film layer 2 (the same as shown in the embodiment of FIG. 1), wherein any two adjacent thin film layers of the plurality of thin film layers 6 are made of different materials. That is that the first thin film layer 2 and the second thin film layer 3 are made of different materials. A bottom portion 30 of the second thin film layer 3 is located between the substrate 10 and the bottom portion 20 of the first thin film layer 2. The surrounding portion 21 of the first thin film layer 2 is located between a surrounding portion 31 of the second thin film layer 3 and the receiving compartment 5. The second thin film layer 3 is made of at least one material selected from the group consisting of: metal, alloy, oxide, nitride and sulfide. In some embodiments, the metal is at least one selected from the group consisting of: Be, Mg, Al, Ti, V, Cr. Mn, Fe. Co, Ni, Cu, Zn, Ga, Ge, Y, Zr, Nb, Mo. Ru. Rh, Pd, Ag, Cd, In, Sn, Sb, Hf, Ta, W, Pt. Au, and Pb. In some embodiments, the alloy is at least one selected from the group consisting of: Be alloy, Mg alloy, Al alloy, Ti alloy, V alloy, Cr alloy, Mn alloy, Fe alloy, Co alloy, Ni alloy, Cu alloy, Zn alloy, Ga alloy, Ge alloy, Y alloy, Zr alloy, Nb alloy, Mo alloy, Ru alloy, Rh alloy, Pd alloy, Ag alloy, Cd alloy, In alloy, Sn alloy, Sb alloy, Hf alloy, Ta alloy, W alloy, Pt alloy, Au alloy, and Pb alloy. In some embodiments, the oxide is at least one selected from the group consisting of: aluminum oxide, titanium dioxide, silicon oxide, and zinc oxide. In some embodiments, the nitride is at least one selected from the group consisting of: silicon nitride, gallium nitride, arsenic nitride, and titanium nitride. In some embodiments, the sulfide is at least one selected from the group consisting of: cadmium sulfide, lead sulfide, and molybdenum sulfide. In some preferred embodiments, the first thin film layer 2 is made of at least one material selected from the group consisting of: bronze, brass, nickel alloy (such as Inconel 718Inconel Inconel 718 nickel alloy), stainless steel (such as 316 stainless steel), gold, silver, and zinc oxide; the second thin film layer 3 is made of at least one material selected from the group consisting of: bronze, brass, nickel alloy (such as Inconel 718 nickel alloy), stainless steel (such as 316 stainless steel), gold, silver, and zinc oxide. In some embodiments, the thickness of the first thin film layer 2 is greater than or equal to 5 nm, and less than or equal to 1 μm; the second thin film layer 3 has a thickness, the thickness of the second thin film layer 3 is greater than or equal to 5 nm, and less than or equal to 1 μm; the thickness of the nanotube (that is the sum of the thickness of the first thin film layer 2 and the thickness of the second thin film layer 3) is greater than or equal to 10 nm, and less than or equal to 2 μm. Since, the first thin film layer 2 and the second thin film layer 3 are made of different materials, the highly-ordered nano-structure array 1 can be applied to the desired field by selecting different combination of materials of the first thin film layer 2 and the second thin film layer 3.

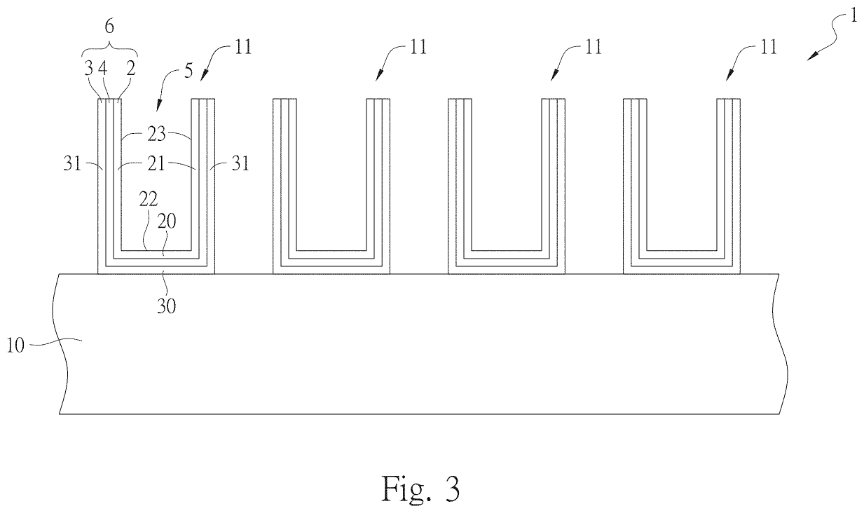

Please refer to FIG. 3, which is the cross-sectional schematic showing an embodiment of a highly-ordered nano-structure array of the present invention. The main structure of the embodiment of FIG. 3 is basically the same as the structure of the embodiment of FIG. 2, except that the plurality of thin film layers 6 further comprises a third thin film layer 4, wherein the third thin film layer 4 is formed between the first thin film layer 2 and the second thin film layer 3, wherein any two adjacent thin film layers of the plurality of thin film layers 6 are made of different materials. That is that the first thin film layer 2 and the third thin film layer 4 are made of different materials; the third thin film layer 4 and the second thin film layer 3 are made of different materials. The third thin film layer 4 is made of at least one material selected from the group consisting of: metal, alloy, oxide, nitride, sulfide, carbide and diamond. In some embodiments, the third thin film layer 4 is made of at least one material selected from the group consisting of: metal, alloy, oxide, nitride and sulfide. In some embodiments, the metal is at least one selected from the group consisting of: Be, Mg, Al, Ti, V, Cr, Mn, Fe, Co, Ni, Cu, Zn, Ga, Ge, Y, Zr, Nb, Mo, Ru, Rh, Pd, Ag, Cd, In, Sn, Sb, Hf, Ta, W. Pt, Au, and Pb. In some embodiments, the alloy is at least one selected from the group consisting of: Be alloy, Mg alloy, Al alloy, Ti alloy, V alloy, Cr alloy, Mn alloy, Fe alloy, Co alloy, Ni alloy, Cu alloy, Zn alloy, Ga alloy, Ge alloy, Y alloy, Zr alloy, Nb alloy, Mo alloy. Ru alloy, Rh alloy, Pd alloy, Ag alloy, Cd alloy, In alloy, Sn alloy, Sb alloy, Hf alloy, Ta alloy, W alloy, Pt alloy, Au alloy, and Pb alloy. In some embodiments, the oxide is at least one selected from the group consisting of: aluminum oxide, titanium dioxide, silicon oxide, and zinc oxide. In some embodiments, the nitride is at least one selected from the group consisting of: silicon nitride, gallium nitride, arsenic nitride, and titanium nitride. In some embodiments, the sulfide is at least one selected from the group consisting of: cadmium sulfide, lead sulfide, and molybdenum sulfide. In some embodiments, the carbide is at least one selected from the group consisting of: silicon carbide, tungsten carbide, iron carbide, and titanium carbide. In some preferred embodiments, the third thin film layer 4 is made of at least one material selected from the group consisting of: bronze, brass, nickel alloy (such as Inconel 718 nickel alloy), stainless steel (such as 316 stainless steel), gold, silver, zinc oxide, silicon carbide, tungsten carbide, diamond, tungsten, tungsten alloy, tungsten nickel alloy, and WNiB metallic glass. In some embodiments, the third thin film layer 4 has a thickness, the thickness of the third thin film layer 4 is greater than or equal to 5 nm, and less than or equal to 1 μm. Since, the first thin film layer 2 and the third thin film layer 4 are made of different materials and the second thin film layer 3 and the third thin film layer 4 are made of different materials, the highly-ordered nano-structure array 1 can be applied to the desired field by selecting different combination of materials of the first thin film layer 2, the second thin film layer 3, and the third thin film layer 4.

In some embodiments, the first thin film layer 2 and the second thin film layer 3 are made of the same material. Hence, the third thin film layer 4 is an inner core layer, while the first thin film layer 2 and the second thin film layer 3 are the outer shell layers. The characteristics of the first thin film layer 2 (the second thin film layer 3) and the characteristics of the third thin film layer 4 will affect each other. By selecting appropriate combination of materials of the first thin film layer 2 (the second thin film layer 3) and the third thin film layer 4, the highly-ordered nano-structure array 1 can be applied to the desired field. In some other embodiments, the first thin film layer 2 and the second thin film layer 3 are made of the same material, and wherein the first thin film layer 2 is made of at least one material selected from the group consisting of: bronze, brass, nickel alloy (such as Inconel 718 nickel alloy), stainless steel (such as 316 stainless steel), gold, silver, and zinc oxide. In some embodiments, the third thin film layer 4 is made of at least one material selected from the group consisting of: bronze, brass, nickel alloy (such as Inconel 718 nickel alloy), stainless steel (such as 316 stainless steel), gold, silver, zinc oxide, silicon carbide, tungsten carbide, diamond, tungsten, tungsten alloy, tungsten nickel alloy, and WNiB metallic glass, and wherein the first thin film layer 2 and the second thin film layer 3 are made of the same material. In some other embodiments, the third thin film layer 4 is made of at least one material selected from the group consisting of: bronze, brass, nickel alloy (such as Inconel 718 nickel alloy), stainless steel (such as 316 stainless steel), gold, silver, zinc oxide, silicon carbide, tungsten carbide, diamond, tungsten, tungsten alloy, tungsten nickel alloy, and WNiB metallic glass, wherein the first thin film layer 2 and the second thin film layer 3 are made of the same material, and wherein the first thin film layer 2 is made of at least one material selected from the group consisting of: bronze, brass, nickel alloy (such as Inconel 718 nickel alloy), stainless steel (such as 316 stainless steel), gold, silver, and zinc oxide.

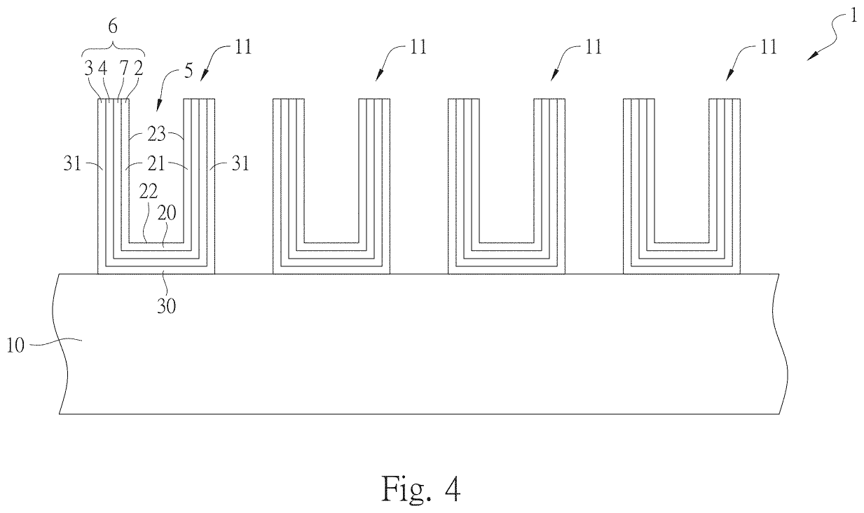

Please refer to FIG. 4, which is the cross-sectional schematic showing another embodiment of a highly-ordered nano-structure array of the present invention. The main structure of the embodiment of FIG. 4 is basically the same as the structure of the embodiment of FIG. 3, except that the plurality of thin film layers 6 further comprises at least one fourth thin film layer 7, wherein the at least one fourth thin film layer 7 is formed between the first thin film layer 2 and the third thin film layer 4, wherein any two adjacent thin film layers of the plurality of thin film layers 6 are made of different materials. That is that the first thin film layer 2 and the at least one fourth thin film layer 7 are made of different materials: the at least one fourth thin film layer 7 and the third thin film layer 4 are made of different materials: the third thin film layer 4 and the second thin film layer 3 are made of different materials. The at least one fourth thin film layer 7 is made of at least one material selected from the group consisting of: metal, alloy, oxide, nitride, sulfide, carbide and diamond. In some embodiments, the at least one fourth thin film layer 7 is made of at least one material selected from the group consisting of: metal, alloy, oxide, nitride and sulfide. In some embodiments, the metal is at least one selected from the group consisting of: Be, Mg, Al, Ti, V, Cr, Mn, Fe, Co, Ni, Cu, Zn, Ga, Ge, Y, Zr, Nb, Mo, Ru, Rh, Pd, Ag, Cd, In, Sn, Sb, Hf, Ta, W, Pt, Au, and Pb. In some embodiments, the alloy is at least one selected from the group consisting of: Be alloy. Mg alloy, Al alloy, Ti alloy. V alloy, Cr alloy, Mn alloy, Fe alloy, Co alloy, Ni alloy, Cu alloy, Zn alloy, Ga alloy, Ge alloy, Y alloy, Zr alloy, Nb alloy, Mo alloy, Ru alloy, Rh alloy, Pd alloy, Ag alloy, Cd alloy, In alloy, Sn alloy, Sb alloy, Hf alloy, Ta alloy, W alloy, Pt alloy, Au alloy, and Pb alloy. In some embodiments, the oxide is at least one selected from the group consisting of: aluminum oxide, titanium dioxide, silicon oxide, and zinc oxide. In some embodiments, the nitride is at least one selected from the group consisting of: silicon nitride, gallium nitride, arsenic nitride, and titanium nitride. In some embodiments, the sulfide is at least one selected from the group consisting of: cadmium sulfide, lead sulfide, and molybdenum sulfide. In some embodiments, the carbide is at least one selected from the group consisting of: silicon carbide, tungsten carbide, iron carbide, and titanium carbide. In some embodiments, the at least one fourth thin film layer 7 is made of at least one material selected from the group consisting of: bronze, brass, nickel alloy (such as Inconel 718 nickel alloy), stainless steel (such as 316 stainless steel), gold, silver, zinc oxide, silicon carbide, tungsten carbide, diamond, tungsten, tungsten alloy, tungsten nickel alloy, and WNiB metallic glass. By selecting appropriate combination of materials of the first thin film layer 2, the second thin film layer 3, the third thin film layer 4, and the at least one fourth thin film layer 7 (wherein any two adjacent thin film layers of the plurality of thin film layers 6 are made of different materials), the highly-ordered nano-structure array 1 can be applied to the desired field.

In some embodiments, the at least one fourth thin film layer 7 is formed between the second thin film layer 3 and the third thin film layer 4 (not shown in Figure), wherein any two adjacent thin film layers of the plurality of thin film layers 6 are made of different material; that is that the second thin film layer 3 and the at least one fourth thin film layer 7 are made of different materials; and the at least one fourth thin film layer 7 and the third thin film layer 4 are made of different materials. In some other embodiments, the at least one fourth thin film layer 7 is formed between the first thin film layer 2 and the third thin film layer 4 and formed between the and the second thin film layer 3 and the third thin film layer 4 (not shown in Figure), wherein any two adjacent thin film layers of the plurality of thin film layers 6 are made of different material; that is that the first thin film layer 2 and the at least one fourth thin film layer 7 are made of different materials; the third thin film layer 4 and the at least one fourth thin film layer 7 are made of different materials; the second thin film layer 3 and the at least one fourth thin film layer 7 are made of different materials.

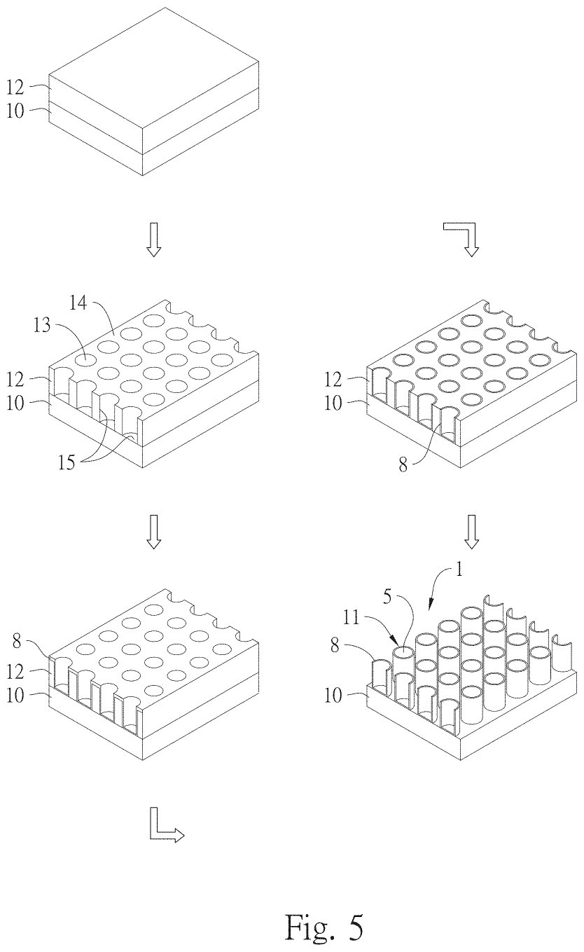

Please refer to FIG. 5, which is the perspective schematic view showing the fabricating processes of a highly-ordered nano-structure array of the present invention. The present invention provides a fabricating method of highly-ordered nano-structure array, which comprises following steps of: Step A: providing a substrate 10, and forming a sacrificial layer 12 on the substrate 10 (as shown in top left of FIG. 5). The substrate 10 may be a silicon substrate. The material of the sacrificial layer 12 may be a photoresist. The photoresist may be a positive photoresist or a negative photoresist. The photoresist is formed on the substrate 10 by coating. In a preferred embodiment, the material of the substrate 10 is suitable for forming at least one thin film layer 8 and the sacrificial layer 12. Step B: patterning the sacrificial layer 12 to provide a plurality of recesses 13 (as shown in middle left of FIG. 5). In current Step, the sacrificial layer 12 is patterned through exposure and development, and then the sacrificial layer 12 is etched to form the plurality of recesses 13. Step C: forming at least one thin film layer 8 on a top surface 14 of the sacrificial layer 12 and an inner surface 15 of each of the recesses 13 (as shown in bottom left of FIG. 5). The method of formation is physical vapor deposition (PVD), for example sputtering. In some embodiments, the at least one thin film layer 8 may be the same as in the embodiment of FIG. 1 having only one first thin film layer. When forming the at least one thin film layer 8 composed of metal or alloy, the target material(s) of metal or alloy is formed on the top surface 14 of the sacrificial layer 12 and the inner surface 15 of each of the recesses 13 by sputtering, so that the at least one thin film layer 8 composed of metal or alloy is formed. When forming the at least one thin film layer 8 composed of oxide, nitride, or sulfide, the target material(s) needs to be replaced by the corresponding target material(s); and then, during sputtering process, oxygen, nitrogen, or sulfurous steam is introduced such that the at least one thin film layer 8 composed of oxide, nitride, or sulfide is formed on the top surface 14 of the sacrificial layer 12 and the inner surface 15 of each of the recesses 13. In some other embodiments, the at least one thin film layer 8 may be the same as in the embodiments of FIGS. 2, 3, and 4 having the plurality of thin film layers 6. For example, when the at least one thin film layer 8 is the same as the embodiment of FIG. 3 having the plurality of thin film layers 6 (including the first thin film layer 2, the second thin film layer 3, and the third thin film layer 4), by physical vapor deposition in sequence, firstly forming the second thin film layer 3 on the top surface 14 of the sacrificial layer 12 and the inner surface 15 of each of the recesses 13; then forming the third thin film layer 4 on an outer surface of the second thin film layer 3; and then forming the first thin film layer 2 on an outer surface of the third thin film layer 4. Step D: etching the at least one thin film layer 8 formed on the top surface 14 of the sacrificial layer 12 such that the sacrificial layer 12 is exposed (as shown in top right of FIG. 5). And Step E: removing the sacrificial layer 12 to form a highly-ordered nano-structure array 1 (as shown in bottom right of FIG. 5), wherein the highly-ordered nano-structure array 1 comprises a plurality of highly-ordered nano-structure units 11: each of the highly-ordered nano-structure units 11 forms a receiving compartment 5; one end of the receiving compartment 5 opposite to the substrate 10 has an opening.

In some embodiments, the sacrificial layer 12 is a semiconductor epitaxial layer epitaxial grown on the substrate 10, wherein the substrate 10 may be a silicon substrate, a semiconductor substrate, or a compound semiconductor substrate (such as GaAs substrate, SiC substrate, or InP substrate). In some other embodiments, the material of the sacrificial layer 12 is metal or alloy, such as TiW. In some embodiments, the substrate 10 is made of GaAs, the sacrificial layer 12 is made of GaAs. In some embodiments, the substrate 10 is made of InP, the sacrificial layer 12 is made of InGaAs. In some embodiments, the substrate 10 is made of silicon, the sacrificial layer 12 is made of TiW.

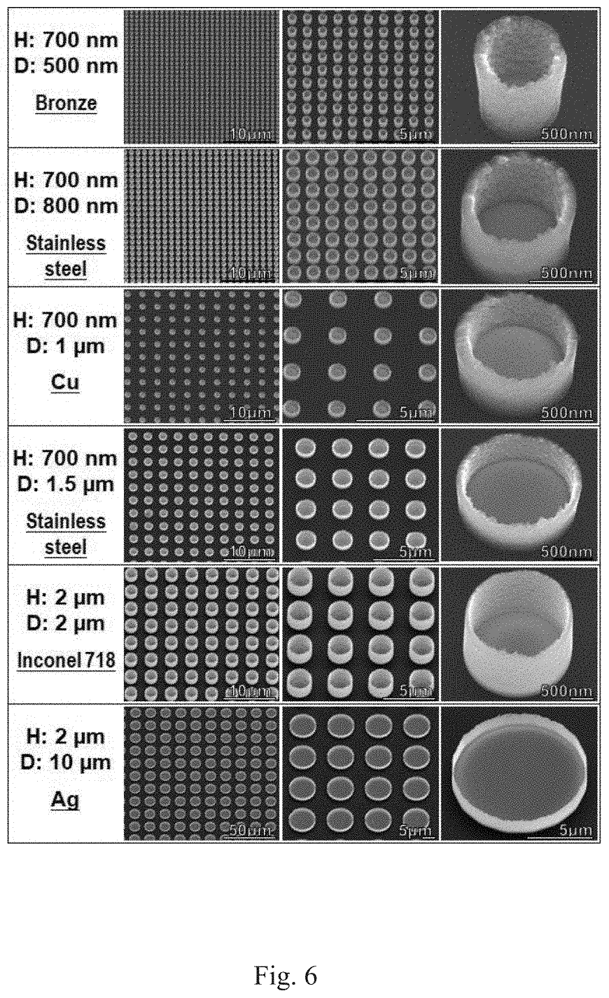

Please refer to FIG. 6, which shows the images of the scanning electron microscope of embodiments of a highly-ordered nano-structure array of the present invention. The embodiment of FIG. 6 has the same structure as the embodiment of FIG. 3 (including the first thin film layer 2, the second thin film layer 3, and the third thin film layer 4), wherein the first thin film layer 2 and the second thin film layer 3 are made of the same material. In FIG. 6, there are six rows in order from top to bottom: each row has three images, and each row represents a combination of materials. The combination of materials in the first row (top row): the first thin film layer 2 and the second thin film layer 3 are made of bronze; the third thin film layer 4 is made of WNiB metallic glass; wherein the height of the nanotube is 700 nm, the diameter of the nanotube is 500 nm. The combination of materials in the second row: the first thin film layer 2 and the second thin film layer 3 are made of 316 stainless steel: the third thin film layer 4 is made of WNiB metallic glass; wherein the height of the nanotube is 700 nm, the diameter of the nanotube is 800 nm. The combination of materials in the third row: the first thin film layer 2 and the second thin film layer 3 are made of copper; the third thin film layer 4 is made of WNiB metallic glass; wherein the height of the nanotube is 700 nm: the diameter of the nanotube is 1 μm. The combination of materials in the fourth row: the first thin film layer 2 and the second thin film layer 3 are made of 316 stainless steel; the third thin film layer 4 is made of WNiB metallic glass; wherein the height of the nanotube is 700 nm; the diameter of the nanotube is 1.5 μm. The combination of materials in the fifth row: the first thin film layer 2 and the second thin film layer 3 are made of Inconel 718 nickel alloy; the third thin film layer 4 is made of WNiB metallic glass; wherein the height of the nanotube is 2 μm; the diameter of the nanotube is 2 μm. The combination of materials in the sixth row (bottom row): the first thin film layer 2 and the second thin film layer 3 are made of Ag; the third thin film layer 4 is made of WNiB metallic glass; wherein the height of the nanotube is 2 μm: the diameter of the nanotube is 10 μm. Therefore, there may be many kinds of combinations.

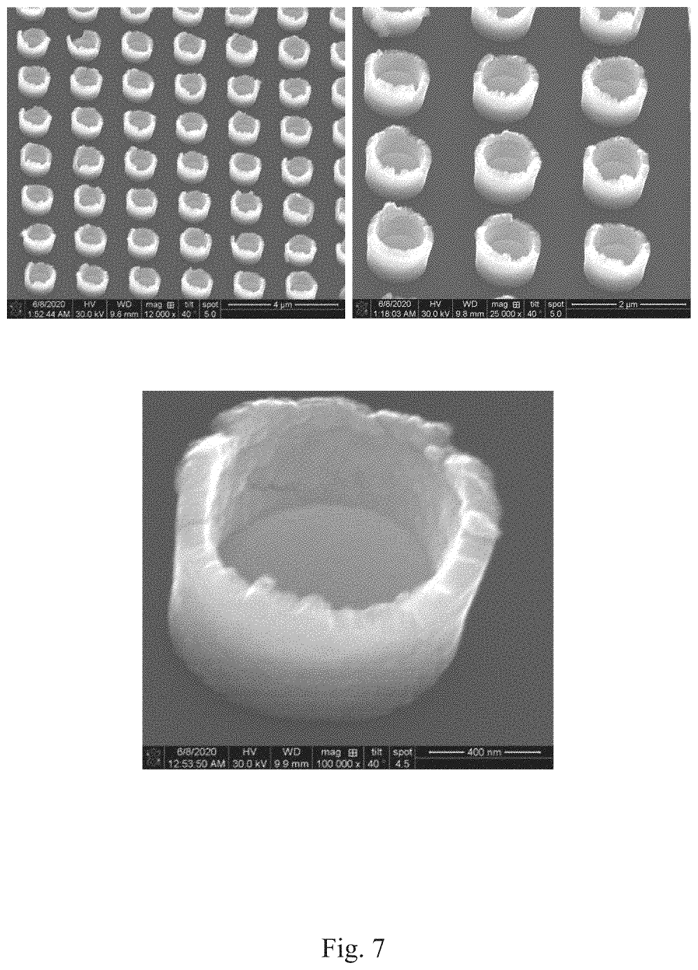

Please refer to FIG. 7, which shows the images of the scanning electron microscope of another embodiment of a highly-ordered nano-structure array of the present invention. The embodiment of FIG. 7 has the same structure as the embodiment of FIG. 1 (a single first thin film layer 2), wherein the first thin film layer 2 is made of ZnO.

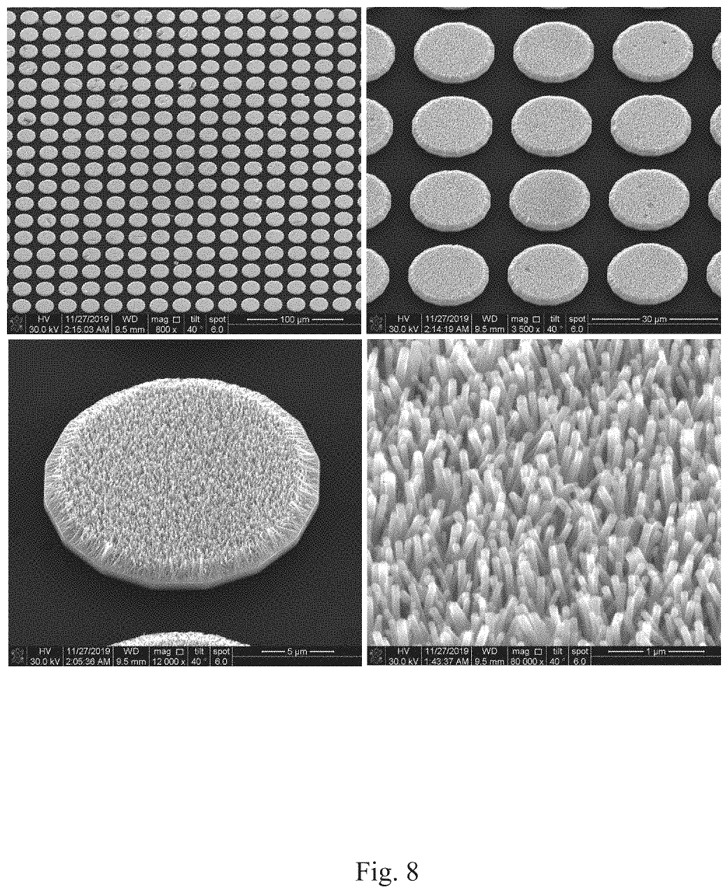

The highly-ordered nano-structure array 1 of the present invention can be used as a carrier to grow some nanostructures, such as nanoparticles, nanowires, etc. Please refer to FIG. 8, which shows the images of the scanning electron microscope of an embodiment of a highly-ordered nano-structure array of the present invention when applied as a carrier. In current Figure, the metal nanotubes array 1 of the present invention is used as a carrier to grow ZnO nanowires. In some embodiments, the highly-ordered nano-structure array 1 of the present invention can be used as a carrier to grow nanoparticles of gold, iron oxide, and other material.

As disclosed in the above description and attached drawings, the present invention can provide a highly-ordered nano-structure array. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A highly-ordered nano-structure array formed on a substrate, wherein said highly-ordered nano-structure array comprises a plurality of highly-ordered nano-structure units, each of said plurality of highly-ordered nano-structure units forms a receiving compartment, one end of said receiving compartment opposite to said substrate has an opening, each of said plurality of highly-ordered nano-structure units comprises:
a first thin film layer, wherein a periphery and a bottom of said receiving compartment are defined by an inner surface of a surrounding portion of said first thin film layer and a top surface of a bottom portion of said first thin film layer respectively, said first thin film layer is made of at least one material selected from the group consisting of: metal, alloy, oxide, nitride and sulfide.

2. The highly-ordered nano-structure array according to claim 1, wherein said first thin film layer is made of at least one material selected from the group consisting of: bronze, brass, nickel alloy, stainless steel, titanium alloy, aluminum alloy, magnesium alloy, molybdenum alloy, tantalum alloy, niobium alloy, cobalt alloy, tin alloy, zinc alloy, zirconium alloy, gold alloy, and silver alloy.

3. The highly-ordered nano-structure array according to claim 1, wherein each of said plurality of highly-ordered nano-structure units has a thickness, said thickness is greater than or equal to 10 nm, and less than or equal to 20 μm, wherein a cross section of each of said plurality of highly-ordered nano-structure units is a triangle, a square, a rectangle, a trapezoid, a circle, an ellipse, or a polygon.

4. The highly-ordered nano-structure array according to claim 1, wherein each of said plurality of highly-ordered nano-structure units has a diameter, said diameter is greater than or equal to 100 nm, and less than or equal to 100 μm.

5. A highly-ordered nano-structure array formed on a substrate, wherein said highly-ordered nano-structure array comprises a plurality of highly-ordered nano-structure units, each of said plurality of highly-ordered nano-structure units forms a receiving compartment, one end of said receiving compartment opposite to said substrate has an opening, each of said plurality of highly-ordered nano-structure units comprises:
a plurality of thin film layers, wherein any two adjacent thin film layers of said plurality of thin film layers are made of different materials, said plurality of thin film layers comprises:
a first thin film layer, wherein a periphery and a bottom of said receiving compartment are defined by an inner surface of a surrounding portion of said first thin film layer and a top surface of a bottom portion of said first thin film layer respectively, said first thin film layer is made of at least one material selected from the group consisting of: metal, alloy, oxide, nitride and sulfide; and
a second thin film layer, wherein a bottom portion of said second thin film layer is located between said substrate and said bottom portion of said first thin film layer, said surrounding portion of said first thin film layer is located between a surrounding portion of said second thin film layer and said receiving compartment, said second thin film layer is made of at least one material selected from the group consisting of: metal, alloy, oxide, nitride and sulfide.

6. The highly-ordered nano-structure array according to claim 5, wherein said first thin film layer is made of at least one material selected from the group consisting of: bronze, brass, nickel alloy, stainless steel, titanium alloy, aluminum alloy, magnesium alloy, molybdenum alloy, tantalum alloy, niobium alloy, cobalt alloy, tin alloy, zinc alloy, zirconium alloy, gold alloy, and silver alloy.

7. The highly-ordered nano-structure array according to claim 6, wherein said second thin film layer is made of at least one material selected from the group consisting of: bronze, brass, nickel alloy, and stainless steel.

8. The highly-ordered nano-structure array according to claim 5, wherein said second thin film layer is made of at least one material selected from the group consisting of: bronze, brass, nickel alloy, and stainless steel.

9. The highly-ordered nano-structure array according to claim 5, wherein each of said plurality of highly-ordered nano-structure units has a thickness, said thickness is greater than or equal to 10 nm, and less than or equal to 20 μm, wherein a cross section of each of said plurality of highly-ordered nano-structure units is a triangle, a square, a rectangle, a trapezoid, a circle, an ellipse, or a polygon.

10. The highly-ordered nano-structure array according to claim 5, wherein each of said plurality of highly-ordered nano-structure units has a diameter, said diameter is greater than or equal to 100 nm, and less than or equal to 100 μm.

11. The highly-ordered nano-structure array according to claim 5, wherein said plurality of thin film layers further comprises a third thin film layer, said third thin film layer is formed between said first thin film layer and said second thin film layer, said third thin film layer is made of at least one material selected from the group consisting of: metal, alloy, oxide, nitride, sulfide, carbide and diamond.

12. The highly-ordered nano-structure array according to claim 11, wherein said first thin film layer is made of at least one material selected from the group consisting of: bronze, brass, nickel alloy, stainless steel, titanium alloy, aluminum alloy, magnesium alloy, molybdenum alloy, tantalum alloy, niobium alloy, cobalt alloy, tin alloy, zinc alloy, zirconium alloy, gold alloy, and silver alloy.

13. The highly-ordered nano-structure array according to claim 12, wherein said first thin film layer and said second thin film layer are made of the same material.

14. The highly-ordered nano-structure array according to claim 13, wherein said third thin film layer is made of at least one material selected from the group consisting of: bronze, brass, nickel alloy, stainless steel, titanium alloy, aluminum alloy, magnesium alloy, molybdenum alloy, tantalum alloy, niobium alloy, cobalt alloy, tin alloy, zinc alloy, zirconium alloy, gold alloy, silver alloy, silicon carbide, tungsten carbide, diamond, tungsten, tungsten alloy, and WNiB metallic glass.

15. The highly-ordered nano-structure array according to claim 12, wherein said third thin film layer is made of at least one material selected from the group consisting of: bronze, brass, nickel alloy, stainless steel, titanium alloy, aluminum alloy, magnesium alloy, molybdenum alloy, tantalum alloy, niobium alloy, cobalt alloy, tin alloy, zinc alloy, zirconium alloy, gold alloy, silver alloy, silicon carbide, tungsten carbide, diamond, tungsten, tungsten alloy, and WNiB metallic glass.

16. The highly-ordered nano-structure array according to claim 11, wherein said first thin film layer and said second thin film layer are made of the same material.

17. The highly-ordered nano-structure array according to claim 16, wherein said third thin film layer is made of at least one material selected from the group consisting of: bronze, brass, nickel alloy, stainless steel, titanium alloy, aluminum alloy, magnesium alloy, molybdenum alloy, tantalum alloy, niobium alloy, cobalt alloy, tin alloy, zinc alloy, zirconium alloy, gold alloy, silver alloy, silicon carbide, tungsten carbide, diamond, tungsten, tungsten alloy, and WNiB metallic glass.

18. The highly-ordered nano-structure array according to claim 11, wherein said third thin film layer is made of at least one material selected from the group consisting of: bronze, brass, nickel alloy, stainless steel, titanium alloy, aluminum alloy, magnesium alloy, molybdenum alloy, tantalum alloy, niobium alloy, cobalt alloy, tin alloy, zinc alloy, zirconium alloy, gold alloy, silver alloy, silicon carbide, tungsten carbide, diamond, tungsten, tungsten alloy, and WNiB metallic glass.

19. The highly-ordered nano-structure array according to claim 11, wherein said plurality of thin film layers further comprises at least one fourth thin film layer, said at least one fourth thin film layer is made of at least one material selected from the group consisting of: metal, alloy, oxide, nitride, sulfide, carbide and diamond, wherein said at least one fourth thin film layer is formed (a) between said third thin film layer and said first thin film layer, (b) between said second thin film layer and said third thin film layer, or (c) between said third thin film layer and said first thin film layer and between said second thin film layer and said third thin film layer.

20. A fabricating method of highly-ordered nano-structure array comprising following steps of:
Step A: forming a sacrificial layer on a substrate, wherein said substrate is a semiconductor substrate, said sacrificial layer is made of at least one material selected from the group consisting of: semiconductor epitaxial structure, metal, and alloy;
Step B: patterning said sacrificial layer to provide a plurality of recesses;
Step C: forming at least one thin film layer on a top surface of said sacrificial layer and an inner surface of each of said plurality of recesses;
Step D: etching said at least one thin film layer formed on said top surface of said sacrificial layer such that said sacrificial layer is exposed; and
Step E: removing said sacrificial layer.
